(19) United States
(12) Patent Application Publication
(10) Pub. No.: US 2009/0014827 A1
(43) Pub. Date: Jan. 15, 2009

(54) Image sensor module at wafer level, method of manufacturing the same, and camera module

(75) Inventors: Chang Hyun Lim, Seoul (KR); Seog Moon Choi, Seoul (KR); Dae Jun Kim, Gyeonggi-do (KR); Won Kyu Jeung, Seoul (KR); Jingli Yuan, Gyeonggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/155,836

(22) Filed: Jun. 10, 2008

(30) Foreign Application Priority Data
Jul. 13, 2007 (KR) 10-2007-0070507

(51) Int. Cl. H01L 31/0203; H01L 31/18

(52) U.S. Cl. 257/434; 438/23; 257/E31.11

(57) ABSTRACT

Provided is an image sensor module at the wafer level including a wafer; an image sensor mounted on one surface of the wafer; a wireless communication chip formed outside the image sensor on the one surface of the wafer; and a protective cover installed on the one surface of the wafer.

### CROSS-REFERENCE TO RELATED APPLICATIONS

This application claims the benefit of Korean Patent Application No. 10-2007-0070507 filed with the Korea Intellectual Property Office on Jul. 13, 2007, the disclosure of which is incorporated herein by reference.

### BACKGROUND OF THE INVENTION

1. Field of the Invention

The present invention relates to an image sensor module at the wafer level, a method of manufacturing the same, and a camera module.

2. Description of the Related Art

One of main trends in the semiconductor industry is to make semiconductor elements as small as possible. In particular, demand for reduction in size is increasing in the semiconductor package industry. Package means sealing integrated circuit (IC) chips through plastic resin or ceramic such that the IC chips can be mounted and used in actual electronic apparatuses.

Conventional typical packages have a much larger size than IC chips built therein. Therefore, package engineers have tried to reduce the size of the packages.

Owing to such an attempt, a new type of packages have been developed, which are referred to as chip-scale packages (or chip-size packages). Among them, wafer level chip scale packages are collectively assembled and manufactured at the wafer level, unlike a typical package manufacturing method in which packages are assembled by the unit of individual chips.

The development of semiconductor IC chips contributes to the development of package technology such that high density, high speed, and reduction in size and thickness are achieved. In particular, the structure of package elements has changed into a surface mount type from a pin insert type or through-hole mount type, thereby increasing mounting density for circuit boards. Recently, studies on chip size packages (CSP), which maintain characteristic of bare chips at the package level and of which the size can be reduced into that of chips, are being actively conducted.

CSP includes a wafer level chip scale package (WLCSP) in which chip pads are rerouted or redistributed on the surface of a chip and solder balls are then formed. In the WLCSP, a chip is directly mounted on a circuit board by a flip-chip method, and the solder ball formed on the redistributed circuit of the chip is bonded to a conductive pad of the circuit board. In this case, the conductive pad may also have a solder ball formed thereon so as to be bonded to the solder ball of the package.

Recently, various CSP technologies which can manufacture packages having almost the same size as that of semiconductor chips have been developed. These technologies are being rapidly spread due to the trend of reduction in size, high speed, and high integration of semiconductor.

With the CSP technology, a wafer-level package technology, in which all the assembling processes are completed at the wafer level that chips are not cut, attracts attention as a next-generation CSP technology. In a current semiconductor assembling process, a wafer is cut into individual chips, and the assembling process is then performed. In the wafer-level package technology, however, a series of assembling processes such as die bonding, wire bonding, and molding are performed at the wafer level, and the wafer is then cut into finalized products.

Therefore, when the wafer-level package technology is applied, it is possible to reduce the entire package cost, compared with the current CSP technology.

In such a WLCSP, solder balls are formed on an active surface of a semiconductor chip. Therefore, when the WLSCP is stacked or applied to the manufacture of sensor packages such as charge coupled devices (CCD), there are structural difficulties.

An image sensor module manufactured by the above-described WLSCP technology is disclosed in Korean Patent Laid-open Publication No. 2002-74158. FIG. 1 shows the structure of the image sensor module.

FIG. 1 is a diagram showing an image sensor module having a microlens array 100 formed on a crystal base material 102.

Under the base material 102 having the microlens array 100 formed thereon, a package layer 106 formed of glass is sealed by epoxy 104. An electric contact 108 is formed along the edge of the package layer 106. The electric contact 108 is connected to a bump 110 formed on the bottom surface of the package layer 106, and is electrically connected to a conductive pad 112 formed on the top surface of the base material 102.

A package layer 114 formed of glass and a spacer element 116 formed under the package layer 114 are sealed by an adhesive such as epoxy 118 such that an cavity 120 can be formed between the microlens array 100 and the package layer 114.

The electric contact 108 is formed on the inclined surfaces of the epoxy 104 and the package layer 106 by a plating method or the like.

In the conventional image sensor module, however, a separate process for the electric connection between the top and bottom surfaces should be performed. Therefore, the number of processes increases, and the structure thereof becomes complex. Accordingly, production speed and productivity decrease, and a manufacturing cost increases.

Further, since the conventional image sensor module is installed in a mobile terminal so as to be used, the image sensor module should be electrically connected to a main circuit board of the mobile terminal, and a sufficient space for driving should be secured in the mobile terminal, which makes it difficult to achieve a reduction in thickness of the mobile terminal.

### SUMMARY OF THE INVENTION

An advantage of the present invention is that it provides an image sensor module at the wafer level, of which the structure is simplified to reduce a manufacturing cost and to enhance productivity and which can be used in various manners, a method of manufacturing the same, and a camera module.

Additional aspects and advantages of the present general inventive concept will be set forth in part in the description which follows and, in part, will be obvious from the description, or may be learned by practice of the general inventive concept.

According to an aspect of the invention, an image sensor module at the wafer level comprises a wafer; an image sensor mounted on one surface of the wafer; a wireless communication chip formed outside the image sensor on the one surface of the wafer; and a protective cover installed on the one surface of the wafer.

The protective cover may have a lead portion projecting from the edge of one surface thereof corresponding to the one surface of the wafer such that an air cavity for sealing the image sensor and the wireless-communication chip is formed, the lead portion being coupled to the edge of the one surface of the wafer through a bonding method.

The protective cover may be formed of any one of glass, quartz, plastic, and polymer.

Preferably, the protective cover is formed in such a manner that a region thereof corresponding to the light receiving region of the image sensor is transparent.

The wireless-communication chip may transmit and receive electrical signals to and from a host of an external terminal through Bluetooth or Zigbee.

The protective cover may have a lead portion projecting from the edge of one surface thereof corresponding to the one surface of the wafer such that an air cavity for sealing only the image sensor is formed, the lead portion being coupled to the one surface of the wafer through a bonding method, and the wireless-communication chip may be formed outside the protective cover.

According to another aspect of the invention, a method of manufacturing an image sensor module at the wafer level comprises the steps of: mounting a plurality of image sensors on one surface of a wafer; forming metal wiring lines to be electrically connected to the image sensors, respectively; forming a plurality of wireless-communication chips on the one surface of the wafer such that the wireless-communication chips are electrically connected to the metal wiring lines, respectively; installing a protective cover on the one surface of the wafer; and dicing the wafer into a plurality of image sensor modules along a scribe line of the wafer.

The metal wiring lines may be formed on the one surface of the wafer having the image sensors mounted thereon, through a metal deposition and patterning process.

The wireless-communication chips may be electrically connected to the metal wiring lines through solder balls.

The protective cover may be installed on the one surface of the wafer through a bonding method.

The protective cover may be installed so as to seal only the image sensors, or is installed so as to simultaneously seal the image sensors and the wireless-communication chips.

According to a further aspect of the invention, an image sensor module at the wafer level comprises a wafer; an image sensor mounted on one surface of the wafer; a wireless communication chip formed outside the image sensor on the one surface of the wafer; a protective cover installed above the one surface of the wafer; and a spacer interposed between the wafer and the protective cover such that the protective cover is spaced at a predetermined distance from the one surface of the wafer.

The spacer may be coupled to the wafer and the protective cover through a bonding method. Further, the spacer may be composed of epoxy containing inorganic balls formed of a metallic or non-metallic material.

The protective cover may be formed of any one of glass, quartz, plastic, and polymer.

Preferably, the protective cover is formed in such a manner that a region thereof corresponding to the light receiving region of the image sensor is transparent.

The wireless-communication chip may transmit and receive electrical signals to and from a host of an external terminal through Bluetooth or Zigbee.

Preferably, the protective cover and the spacer are provided in such a manner that an air cavity for simultaneously sealing the image sensors and the wireless-communication chips is formed.

The protective cover and the spacer may be provided in such a manner that an air cavity for sealing only the image sensors is formed.

According to a still further aspect of the invention, a method of manufacturing an image sensor module at the wafer level comprises the steps of: mounting a plurality of image sensors on one surface of a wafer; forming metal wiring lines to be electrically connected to the image sensors, respectively; forming a plurality of wireless-communication chips on the one surface of the wafer such that the wireless-communication chips are electrically connected to the metal wiring lines, respectively; forming a spacer on the one surface of the wafer; installing a protective cover on the one surface of the wafer through the spacer; and dicing the wafer into a plurality of image sensor modules along a scribe line of the wafer.

The metal wiring lines may be formed on the one surface of the wafer having the image sensors mounted thereon, through a metal deposition and patterning process.

The wireless-communication chips may be electrically connected to the metal wiring lines through solder balls.

The spacer may be coupled to the wafer and the protective cover through a bonding method. Further, the spacer may be formed so as to be positioned outside the wireless-communication chips.

The spacer may be formed so as to be positioned between the image sensors and the wireless-communication chips.

According to a still further aspect of the invention, an image sensor module at the wafer level comprises a wafer; an image sensor mounted on one surface of the wafer; a wireless-communication chip formed outside the image sensors on the one surface of the wafer; a bonding spacer formed on the one surface of the wafer so as to seal the image sensor and the wireless-communication chip; and a protective cover installed on the bonding spacer so as to protect the image sensors and the wireless-communication chip from outside.

The bonding spacer may be formed of a transparent material with an adhesive property.

The protective cover may be formed of any one of glass, quartz, plastic, and polymer.

The protective cover may be formed in such a manner that a region thereof corresponding to the light receiving region of the image sensor is transparent.

The wireless-communication chip may transmit and receive electrical signals to and from a host of an external terminal through Bluetooth or Zigbee.

According to a still further aspect of the invention, an image sensor module at the wafer level comprises a wafer; an image sensor mounted on one surface of the wafer; a wireless-communication chip formed outside the image sensor on the one surface of the wafer; a bonding spacer formed on the one surface of the wafer so as to seal only the image sensor; and a protective cover installed on the bonding spacer so as to protect the image sensors from outside.

According to a still further aspect of the invention, a method of manufacturing an image sensor module at the wafer level comprises the steps of: mounting a plurality of image sensors on one surface of a wafer; forming metal wiring lines to be electrically connected to the image sensors, respectively; forming a plurality of wireless-communication chips on the one surface of the wafer such that the wireless-communication chips are electrically connected to the metal wiring lines, respectively; applying a bonding spacer on the one surface of the wafer; installing a protective cover on the one surface of the wafer through the bonding spacer; and dicing the wafer into a plurality of image sensor modules along a scribe line of the wafer.

The metal wiring lines may be formed on the one surface of the wafer having the image sensors mounted thereon, through a metal deposition and patterning process.

The wireless-communication chips may be electrically connected to the metal wiring lines through solder balls.

The bonding spacer may be applied so as to simultaneously seal the image sensors and the wireless-communication chips.

The bonding spacer may be applied so as to seal only the image sensors.

According to a still further aspect of the invention, an image sensor module comprises a semiconductor element having an image sensor formed on the central region thereof and a wireless-communication chip formed on the edge thereof through a semiconductor process.

The image sensor module may further comprise a protective cover for protecting the semiconductor element.

According to a still further aspect of the invention, a camera module comprises an image sensor module at the wafer level including a wafer; an image sensor mounted on one surface of the wafer; a wireless communication chip formed outside the image sensor on the one surface of the wafer; and a protective cover installed on the one surface of the wafer.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a conventional image sensor module;

FIG. 2 is a cross-sectional view of an image sensor module according to a first embodiment of the invention;

FIG. 3 is a plan view of the image sensor module according to the first embodiment of the invention, showing a state where a cover is removed;

FIGS. 4 to 6 are process diagrams sequentially showing a method of manufacturing the image sensor module according to a first embodiment of the invention;

FIG. 7 is a cross-sectional view of an image sensor module according to a second embodiment of the invention;

FIG. 8 is a cross-sectional view of an image sensor module having a different structure from the image sensor module according to the second embodiment of the invention;

FIG. 9 is a plan view of the image sensor module of FIG. 8, showing a state where a cover is removed.

FIG. 10 is a cross-sectional view of an image sensor module according to a third embodiment of the invention.

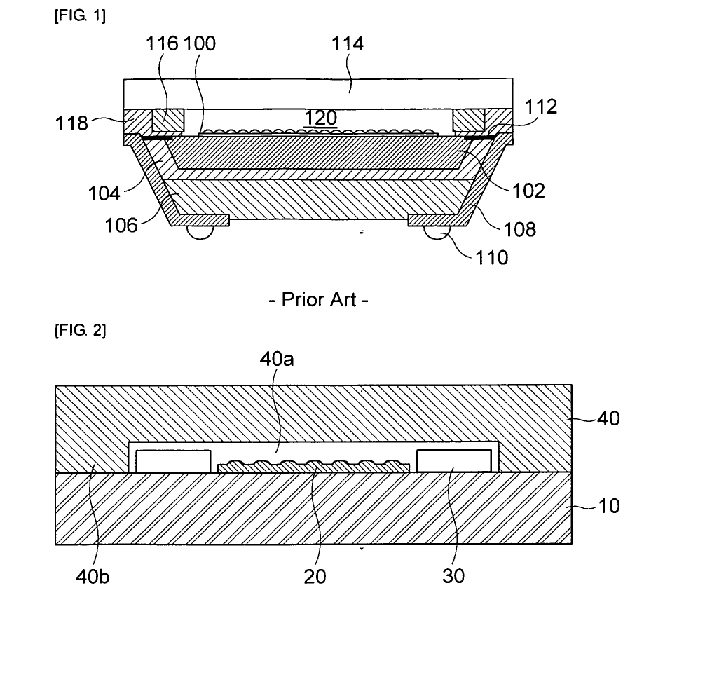

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, an image sensor module at the wafer level, a method of manufacturing the same, and a camera module according to the present invention will be described in detail with reference to the accompanying drawings.

### First Embodiment

Referring to FIGS. 2 to 6, an image sensor module at the wafer level according to a first embodiment of the invention will be described.

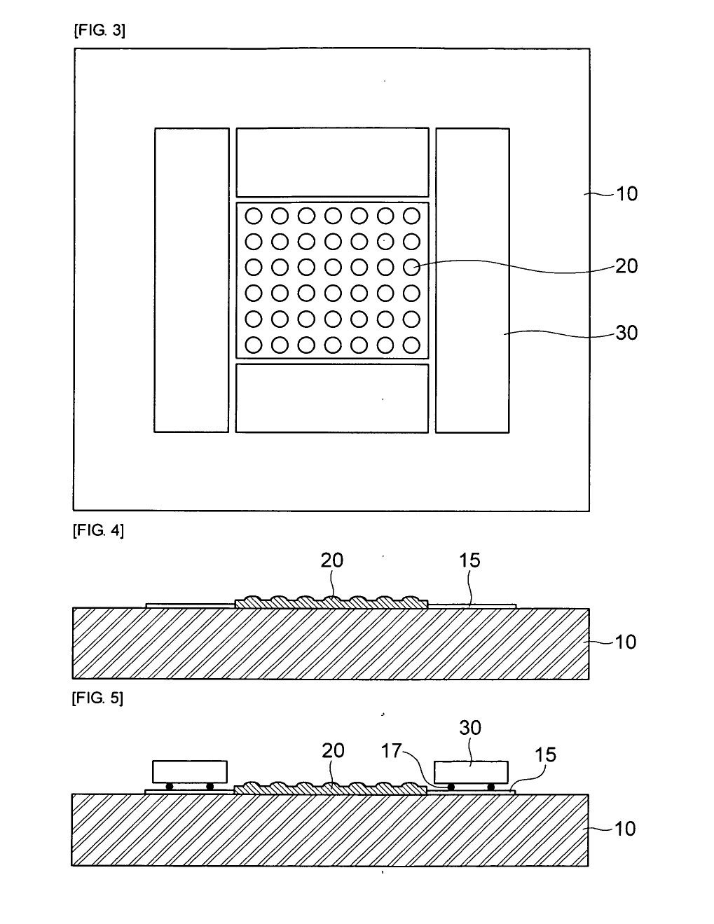

As shown in FIGS. 2 and 3, the image sensor module at the wafer level according to the first embodiment of the invention includes a wafer 10, an image sensor 20 mounted on the top surface of the wafer 10, a wireless-communication chip 30 formed outside the image sensor. 20 on the top surface of the wafer 10, and a protective cover 40 installed on the wafer 10.

The protective cover 40 facing the top surface of the wafer 10 has a lead portion 40b projecting along the edge of the bottom surface thereof such that an air cavity 40a is formed between the protective cover 40 and the wafer 10. Inside the air cavity 40a, the image sensor 20 and the wireless-communication chip 30 are sealed. The lead portion 40b is coupled to the edge of the top surface of the wafer 10 through a bonding method.

The protective cover 40 may be formed of any one of glass, quartz, plastic, and polymer. Preferably, a portion of the protective cover 40 corresponding to the light receiving region of the image sensor 20 is set to be transparent in such a manner that light can be incident on the image sensor 20.

The wireless-communication chip 30 serves to transmit and receive electrical signals to and from a host of an external terminal through a wireless communication scheme such as Bluetooth or Zigbee.

For example, when Bluetooth is applied to the wireless-communication chip 30, the wireless-communication chip 30 compresses electrical signals for an image, converted by the image sensor 20, into MP4 or H.264 data, and then converts the compressed data into Bluetooth data packets to transmit to the host of the external terminal. The host demodulates the received Bluetooth data packets to recover the MP4 or H.264 data, and then reproduces the data through a decoder. On the other hand, the wireless-communication chip 30 receives data such as a driving signal of the image sensor 20 from the host of the external terminal through wireless communication and then controls the driving of the image sensor 20.

Therefore, the image sensor module does not need to be installed in the host of the external terminal, and complex wiring lines for electric connection with the external terminal do not need to be installed. Further, since the image sensor module can be separated from the external terminal, the image sensor module can be separately attached to glasses or clothes so as to be used in various manners.

Further, since the image sensor module at the wafer level can be driven separately from the external terminal, a space required for the image sensor module and the wiring lines in the external terminal is removed. Therefore, it is possible to achieve a reduction in size and thickness of the external terminal, thereby increasing a degree of freedom in design.

Further, the lead portion may be formed to project from the edge of the bottom surface of the protective cover corresponding to the top surface of the wafer such that the air cavity for sealing only the image sensor formed and the lead portion is coupled to the top surface of the wafer through the bonding method. The wireless-communication chip may be formed outside the protective cover.

That is, the wireless-communication chip may be formed on the edge of the top surface of the wafer such that the size of the protective cover is reduced while the height thereof is maintained, and the distance from the image sensor increases. Then, the lead portion formed on the protective cover is coupled between the image sensor and the wireless-communication chip on the top surface of the wafer through the bonding method.

Now, a method of manufacturing the image sensor module at the waver level according to the first embodiment of the invention will be described with reference to FIGS. 4 to 6.

First, as shown in FIG. 4, a plurality of image sensors 20 are mounted on the top surface of the wafer 10, and metal wiring lines 15 are formed so as to be connected to the image sensors 20, respectively.

The metal wiring lines 15 may be formed on the top surface of the wafer 10 having the image sensors 20 mounted thereon through a metal deposition and pattering process.

Then, as shown in FIG. 5, a plurality of wireless-communication chips 30 are formed on the top surface of the wafer 10 so as to be electrically connected to the metal wiring lines 15, respectively.

The forming of the wireless-communication chips 30 may be performed through solder balls.

Subsequently, as shown in FIG. 6, a protective cover 40 is installed on the top surface of the wafer 10 through the bonding method.

As described above, the protective cover 40 is installed in such a manner that the image sensors 20 and the wireless-communication chips 30 are sealed together. However, the protective cover 40 may be formed with such a size that only the image sensors 20 are sealed.

Then, as the wafer 10 is diced along the scribe line of the wafer 10, the image sensor modules at the wafer level according to the first embodiment of the invention are completely manufactured.

### Second Embodiment

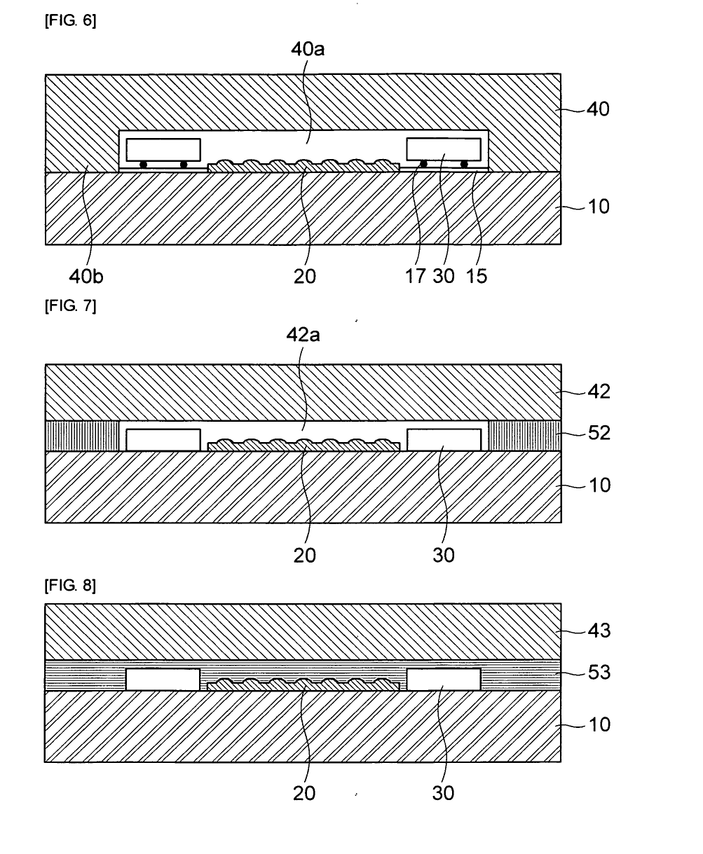

Referring to FIGS. 7 to 9, an image sensor module at the wafer level according to a second embodiment of the invention will be described.

As shown in FIG. 7, the image sensor module at the wafer level according to the second embodiment of the invention includes a wafer 10, an image sensor 20 mounted on the top surface of the wafer 10, a wireless-communication chip 30 formed outside the image sensor 20 on the top surface of the wafer 10, a protective cover 42 installed above the wafer 10, and a spacer 52 interposed between the wafer 10 and the protective cover 42 such that the protective cover 42 is spaced at a predetermined distance from the top surface of the wafer 10.

The spacer 52 may be coupled to the wafer 10 and the protective cover 42 through the bonding method.

That is, the spacer 52, which is composed of an adhesive such as epoxy containing inorganic balls formed of a metallic or non-metallic material, is installed on the top surface of the wafer 10 so as to be coupled to the wafer 10 through the bonding method. Therefore, the height of the image sensor module can be maintained at a predetermined level. Further, the edge of the protective cover 42 can be coupled and fixed to the top surface of the spacer 52 through the bonding method.

Similar to the first embodiment, the protective cover 42 is formed of any one of glass, quartz, plastic, and polymer. Preferably, a portion of the protective cover 42 corresponding to light receiving regions of the image sensor 20 is set to be transparent.

The wireless-communication chip 30 serves to transmit and receive electrical signals to and from a host of an external terminal through a wireless communication scheme such as Bluetooth or Zigbee. The detailed descriptions of the wireless-communication chip 30 are omitted, because the construction thereof is the same as that of the wireless-communication chip 30 of the first embodiment.

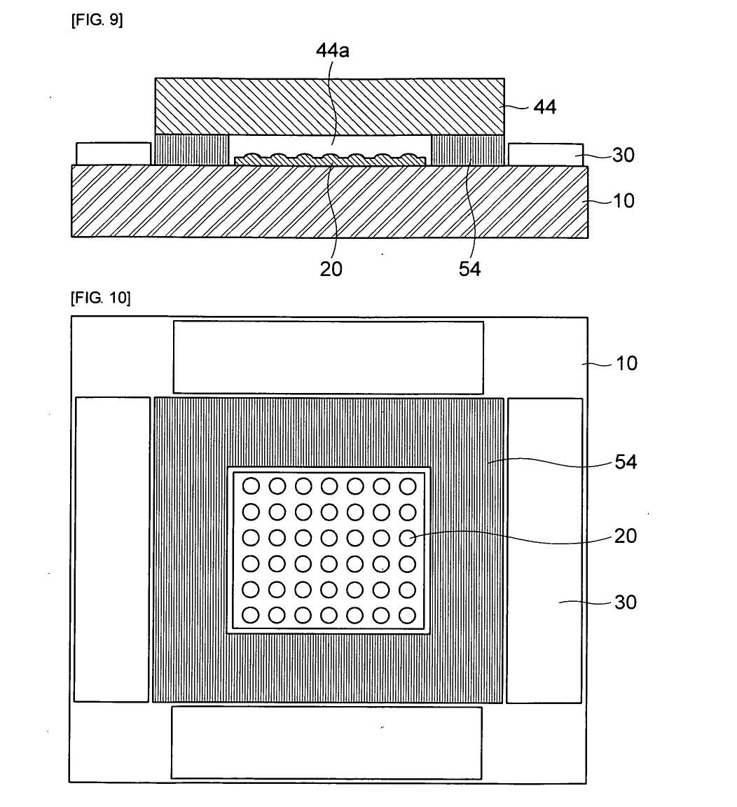

The protective cover 42 and the spacer 52 may be provided in such a manner that an air cavity 42a for simultaneously sealing the image sensor 20 and the wireless-communication chip 30 is formed. As shown in FIGS. 8 and 9, however, a protective cover 44 and a spacer 52 may be provided in such a manner that an air cavity 44a for sealing only the image sensor 20 is formed.

That is, the communication chip 30 is mounted on the outermost portion of the top surface of the wafer 10 such that the distance between the communication chip 30 and the image sensor module 20 increases, the spacer 54 is installed between the image sensor 20 and the communication chip 30 on the top surface of the wafer 10, and the protective cover 44 is formed with such a size as to correspond to the spacer 54. Then, only the image sensor 20 can be sealed by the protective cover 44 and the spacer 52.

Now, a method of manufacturing the image sensor module at the wafer lever according to the second embodiment of the invention will be described with reference to FIGS. 7 to 9.

First, a plurality of image sensor modules 20 are mounted on the top surface of the wafer 10, and metal wiring lines (not shown) are formed so as to be electrically connected to the image sensors 20, respectively.

Similar to the first embodiment, the metal wiring lines may be formed on the top surface of the wafer 10 having the image sensors 20 mounted thereon through a metal deposition and pattering process.

Then, a plurality of communication chips 30 are mounted on the top surface of the wafer 10 so as to be electrically connected to the metal wiring lines, respectively.

Similar to the first embodiment, the forming of the wireless-communication chips 30 may be performed through solder balls.

Then, a spacer 52 or 54 is formed on the top surface of the wafer 10 through the bonding method, and a protective cover 42 or 44 is installed on the spacer 52 or 54 through the bonding method.

Therefore, the protective cover 42 or 44 is installed in such a manner that a distance from the top surface of the wafer 10, corresponding to the height of the spacer 52 or 54, is maintained through the spacer 52 or 54. Accordingly, the image sensors 20 and the wireless-communication chips 30 are sealed together or only the image sensors 20 are sealed by the protective cover 42 or 44 and the spacer 52 or 54.

Then, as the wafer 10 is diced along the scribe line of the wafer 10, the image sensor modules at the wafer level according to the second embodiment of the invention are completely manufactured.

### Third Embodiment

Referring to FIG. 10, an image sensor module at the wafer level according to a third embodiment of the invention will be described.

As shown in FIG. 10, the image sensor module at the wafer level according to the third embodiment includes a wafer 10, an image sensor 20 mounted on the top surface of the wafer 10, a wireless-communication chip 30 formed outside the image sensor 20 on the top surface of the wafer 10, a bonding spacer 53 formed on the top surface of the wafer 10 so as to seal the image sensor 20 and the wireless-communication chip 30, and a protective cover 43 installed on the bonding spacer 53 so as to protect the image sensor 20 and the wireless-communication chip 30 from outside.

Preferably, the bonding spacer 53 is formed of a transparent material with an adhesive property.

That is, since the bonding spacer 53 formed of a transparent material with an adhesive property is applied across the entire top surface of the wafer 10 so as to fixed, the image sensor 20 and the wireless-communication chip 30 are sealed by the bonding spacer 53, and light is smoothly incident on the light receiving region of the image sensor 20. Further, the protective cover 43 is coupled and fixed to the bonding spacer 53 through the bonding method such that a distance from the top surface of the wafer 10, corresponding to the height of the bonding spacer 53, is maintained.

Similar to the first embodiment, the protective cover 43 is formed of any one of glass, quartz, plastic, and polymer. Preferably, a portion of the protective cover 43 corresponding to the light receiving region of the image sensor 20 is set to be transparent.

The wireless-communication chip 30 serves to transmit and receive electrical signals to and from a host of an external terminal through a wireless communication scheme such as Bluetooth or Zigbee. The detailed descriptions of the wireless-communication chip 30 are omitted, because the construction thereof is the same as that of the wireless-communication chips 30 of the first embodiment.

As described above, the bonding spacer 53 is applied across the entire top surface of the wafer 10 so as to simultaneously seal the image sensor 20 and the wireless-communication chip 30. However, the bonding spacer 53 may be partially applied on the top surface of the wafer 10 so as to seal only the image sensor 20.

Now, a method of manufacturing the image sensor module at the wafer level according to the third embodiment of the invention will be described with reference to FIG. 10.

First, a plurality of image sensors 20 are mounted on the top surface of the wafer 10, and metal wiring lines (not shown) are formed so as to be electrically connected to the image sensors 20, respectively.

Similar to the first embodiment, the metal wiring lines may be formed on the top surface of the wafer 10 having the image sensors 20 mounted thereon through a metal deposition and pattering process.

Then, a plurality of communication chips 30 are mounted on the top surface of the wafer 10 so as to be electrically connected to the metal wiring lines, respectively.

Similar to the first embodiment, the forming of the wireless-communication chips 30 may be performed through solder balls.

Then, a bonding spacer 53 is applied on the top surface of the wafer 10.

At this time, the bonding spacer 53 may be applied across the entire top surface of the wafer 10 so as to simultaneously seal the image sensors 20 and the wireless-communication chips 30. Alternatively, the bonding spacer 53 may be partially applied on the top surface of the wafer 10 so as to seal only the image sensors 20.

Then, as the wafer 10 is diced along the scribe line of the wafer 10, the image sensor modules at the wafer level according to the third embodiment of the invention are completely manufactured.

### Fourth Embodiment

Unlike the image sensor modules at the wafer level according to the first to third embodiment of the invention, an image sensor module at the wafer level according to a fourth embodiment of the invention includes a semiconductor element and a protective cover for protecting the semiconductor element. The semiconductor element has an image sensor formed on the central region thereof and a wireless-communication chip formed on the edge thereof through a semiconductor process.

That is, since the image sensor is formed on the central region of the semiconductor element and the wireless-communication chip is formed on the edge of the semiconductor element through a semiconductor process, the process of forming metal wiring lines and the process of forming wireless-communication chips in the first to third embodiment can be omitted. Therefore, it is possible to manufacture the image sensor module through a more simple process.

Meanwhile, the image sensor module according to the first to fourth embodiments of the invention can be applied to a general camera module. The camera module to which the image sensor module is applied does not need to be installed inside an external terminal such as a mobile terminal, and does not require complex wiring lines for electric connection with the external terminal. Therefore, since the camera module can be separated from the external terminal, the camera module can be separately attached to glasses or clothes so as to be used in various manners.

According to the present invention, the image sensor module at the wafer level which can perform wireless communication is provided. Therefore, the image sensor module does not need to be installed in a host of an external terminal, and complex wiring lines for electric connection with the external terminal do not need to be formed, which makes it possible to reduce a manufacturing cost and to enhance productivity.

Further, as the image sensor module can be separated from the external terminal, the image sensor module can be separately attached to glasses and clothes so as to be used in various manners.

Further, since the image sensor module can be driven separately from the external terminal, a space required for the image sensor module and the wiring lines in the external terminal is removed. Therefore, it is possible to achieve a reduction in size and thickness of the external terminal, thereby increasing a degree of freedom in design.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. An image sensor module at the wafer level comprising:
a wafer;
an image sensor mounted on one surface of the wafer;
a wireless communication chip formed outside the image sensor on the one surface of the wafer; and
a protective cover installed on the one surface of the wafer.

2. The image sensor module at the wafer level according to claim 1, wherein the protective cover has a lead portion projecting from the edge of one surface thereof corresponding to the one surface of the wafer such that an air cavity for sealing the image sensor and the wireless-communication chip is formed, the lead portion being coupled to the edge of the one surface of the wafer through a bonding method.

3. The image sensor module at the wafer level according to claim 1, wherein the protective cover is formed of any one of glass, quartz, plastic, and polymer.

4. The image sensor module at the wafer level according to claim 1, wherein the protective cover is formed in such a manner that a region thereof corresponding to the light receiving region of the image sensor is transparent.

5. The image sensor module at the wafer level according to claim 1, wherein the wireless-communication chip transmits and receives electrical signals to and from a host of an external terminal through Bluetooth or Zigbee.

6. The image sensor module at the wafer level according to claim 1, wherein the protective cover has a lead portion projecting from the edge of one surface thereof corresponding to the one surface of the wafer such that an air cavity for sealing only the image sensor is formed, the lead portion being coupled to the one surface of the wafer through a bonding method, and
the wireless-communication chip is formed outside the protective cover.

7. A method of manufacturing an image sensor module at the wafer level, comprising:
mounting a plurality of image sensors on one surface of a wafer;
forming metal wiring lines to be electrically connected to the image sensors, respectively;
forming a plurality of wireless-communication chips on the one surface of the wafer such that the wireless-communication chips are electrically connected to the metal wiring lines, respectively;
installing a protective cover on the one surface of the wafer; and
dicing the wafer into a plurality of image sensor modules along a scribe line of the wafer.

8. The method according to claim 7, wherein the metal wiring lines are formed on the one surface of the wafer having the image sensors mounted thereon, through a metal deposition and patterning process.

9. The method according to claim 7, wherein the wireless-communication chips are electrically connected to the metal wiring lines through solder balls.

10. The method according to claim 7, wherein the protective cover is installed on the one surface of the wafer through a bonding method.

11. The method according to claim 7, wherein the protective cover is installed so as to seal only the image sensors, or is installed so as to simultaneously seal the image sensors and the wireless-communication chips.

12. An image sensor module at the wafer level comprising:
a wafer;
an image sensor mounted on one surface of the wafer;
a wireless communication chip formed outside the image sensor on the one surface of the wafer;
a protective cover installed above the one surface of the wafer; and
a spacer interposed between the wafer and the protective cover such that the protective cover is spaced at a predetermined distance from the one surface of the wafer.

13. The image sensor module at the wafer level according to claim 12, wherein the spacer is coupled to the wafer and the protective cover through a bonding method.

14. The image sensor module at the wafer level according to claim 12, wherein the spacer is composed of epoxy containing inorganic balls formed of a metallic or non-metallic material.

15. The image sensor module at the wafer level according to claim 12, wherein the protective cover is formed of any one of glass, quartz, plastic, and polymer.

16. The image sensor module at the wafer level according to claim 12, wherein the protective cover is formed in such a manner that a region thereof corresponding to the light receiving region of the image sensor is transparent.

17. The image sensor module at the wafer level according to claim 12, wherein the wireless-communication chip transmits and receives electrical signals to and from a host of an external terminal through Bluetooth or Zigbee.

18. The image sensor module at the wafer level according to claim 12, wherein the protective cover and the spacer are provided in such a manner that an air cavity for simultaneously sealing the image sensors and the wireless-communication chips is formed.

19. The image sensor module at the wafer level according to claim 12, wherein the protective cover and the spacer are provided in such a manner that an air cavity for sealing only the image sensors is formed.

20. A method of manufacturing an image sensor module at the wafer level, comprising:
mounting a plurality of image sensors on one surface of a wafer;
forming metal wiring lines to be electrically connected to the image sensors, respectively;
forming a plurality of wireless-communication chips on the one surface of the wafer such that the wireless-communication chips are electrically connected to the metal wiring lines, respectively;
forming a spacer on the one surface of the wafer;
installing a protective cover on the one surface of the wafer through the spacer; and
dicing the wafer into a plurality of image sensor modules along a scribe line of the wafer.

21. The method according to claim 20, wherein the metal wiring lines are formed on the one surface of the wafer having the image sensors mounted thereon, through a metal deposition and patterning process.

22. The method according to claim 20, wherein the wireless-communication chips are electrically connected to the metal wiring lines through solder balls.

23. The method according to claim 20, wherein the spacer is coupled to the wafer and the protective cover through a bonding method.

24. The method according to claim 20, wherein the spacer is formed so as to be positioned outside the wireless-communication chips.

25. The method according to claim 20, wherein the spacer is formed so as to be positioned between the image sensors and the wireless-communication chips.

26. An image sensor module at the wafer level comprising:
a wafer;
an image sensor mounted on one surface of the wafer;
a wireless-communication chip formed outside the image sensors on the one surface of the wafer;
a bonding spacer formed on the one surface of the wafer so as to seal the image sensor and the wireless-communication chip; and
a protective cover installed on the bonding spacer so as to protect the image sensors and the wireless-communication chip from outside.

27. The image sensor module at the wafer level according to claim 26, wherein the bonding spacer is formed of a transparent material with an adhesive property.

28. The image sensor module at the wafer level according to claim 26, wherein the protective cover is formed of any one of glass, quartz, plastic, and polymer.

29. The image sensor module at the wafer level according to claim 26, wherein the protective cover is formed in such a manner that a region thereof corresponding to the light receiving region of the image sensor is transparent.

30. The image sensor module at the wafer level according to claim 26, wherein the wireless-communication chip transmits and receives electrical signals to and from a host of an external terminal through Bluetooth or Zigbee.

31. An image sensor module at the wafer level comprising:
a wafer;
an image sensor mounted on one surface of the wafer;
a wireless-communication chip formed outside the image sensor on the one surface of the wafer;
a bonding spacer formed on the one surface of the wafer so as to seal only the image sensor; and
a protective cover installed on the bonding spacer so as to protect the image sensors from outside.

32. A method of manufacturing an image sensor module at the wafer level, comprising:
mounting a plurality of image sensors on one surface of a wafer;
forming metal wiring lines to be electrically connected to the image sensors, respectively;
forming a plurality of wireless-communication chips on the one surface of the wafer such that the wireless-communication chips are electrically connected to the metal wiring lines, respectively;
applying a bonding spacer on the one surface of the wafer;
installing a protective cover on the one surface of the wafer through the bonding spacer; and
dicing the wafer into a plurality of image sensor modules along a scribe line of the wafer.

33. The method according to claim 32, wherein the metal wiring lines are formed on the one surface of the wafer having the image sensors mounted thereon, through a metal deposition and patterning process.

34. The method according to claim 32, wherein the wireless-communication chips are electrically connected to the metal wiring lines through solder balls.

35. The method according to claim 32, wherein the bonding spacer is applied so as to simultaneously seal the image sensors and the wireless-communication chips.

36. The method according to claim 32, wherein the bonding spacer is applied so as to seal only the image sensors.

37. An image sensor module comprising:
a semiconductor element having an image sensor formed on the central region thereof and a wireless-communication chip formed on the edge thereof through a semiconductor process.

38. The image sensor module according to claim 37 further comprising:
a protective cover for protecting the semiconductor element.

39. A camera module comprising:
an image sensor module at the wafer level including:
a wafer;
an image sensor mounted on one surface of the wafer;
a wireless communication chip formed outside the image sensor on the one surface of the wafer; and
a protective cover installed on the one surface of the wafer.
